(19) United States
(12) Patent Application Publication
(10) Pub. No.: US 2012/0152172 A1
(43) Pub. Date: Jun. 21, 2012

(54) GAS-DISCHARGING DEVICE AND SUBSTRATE-PROCESSING APPARATUS USING SAME

(75) Inventors: Hui Hwang, Pyungtaek-Si (KR); Pil-Woong Heo, Pyungtaek-Si (KR); Chang-Hee Han, Pyungtaek-Si (KR)

(73) Assignee: WONIK IPS CO., LTD., Pyeongtaek-Si, Gyeonggi-Do (KR)

(21) Appl. No.: 13/393,911

(22) PCT Filed: Aug. 24, 2010
(86) PCT No.: PCT/KR10/05630

§ 371 Date: Mar. 2, 2012

(30) Foreign Application Priority Data
Sep. 2, 2009 (KR) 10-2009-0082602

(51) Int. Cl. C23C 16/455

(52) U.S. Cl. 118/730

(57) ABSTRACT

Provided are a gas injection device and substrate processing apparatus using the same. The gas injection device includes a plurality of gas injection units disposed above a substrate support part rotatably disposed within a chamber to support a plurality of substrates, the plurality of gas injection units being disposed along a circumference direction with respect to a center point of the substrate support part to inject a process gas onto the substrates. Each of the plurality of gas injection units includes a top plate in which an inlet configured to introduce the process gas is provided and an injection plate disposed under the top plate to define a gas diffusion space between the injection plate and the top plate along a radius direction of the substrate support part, the injection plate having a plurality of gas injection holes under the gas diffusion space to inject the process gas introduced through the inlet and diffused in the gas diffusion space onto the substrate. In at least one gas injection unit of the plurality of gas injection units, a partition wall is disposed between the top plate and the injection plate to divide the gas diffusion space into a plurality of separated spaces along the radius direction of the substrate support part, and the inlet is provided in plurality and the plurality of inlets are respectively provided in the separated spaces so that the process gases are independently introduced into the separated spaces.

### TECHNICAL FIELD

The present disclosure relates to a gas-discharging device and a substrate processing apparatus using the same, and more particularly, to a substrate processing apparatus in which a plurality of substrates are seated on a substrate support part to perform processes such as thin film deposition and a gas injection device used for the substrate processing apparatus.

### BACKGROUND ART

As the scales of semiconductor devices gradually decrease, extreme thin films are increasingly required. In addition, as the sizes of contact holes are reduced, limitations in step coverage are increased more and more. Thus, an atomic layer deposition (ALD) method is being used as deposition methods for addressing these limitations. In general, the ALD method is a method in which various source gases are separately supplied to a substrate to form a thin film through surface saturations of the source gases.

The principle of the ALD method will be simply described below. When a first source gas is supplied into a chamber, the first source gas reacts with a substrate surface. As a result, a monoatomic layer is chemically adsorbed onto the substrate surface. However, when the substrate surface is saturated with the first source gas, the first source gases over the monoatomic layer are physically adsorbed, but chemically adsorbed, due to non-reactivity between the same ligands. When a purge gas is supplied, the first source gases, which are physically adsorbed, are removed by the purge gas.

When a second source gas is supplied on the first monoatomic layer, a second layer is grown through substitution reaction between ligands of the first and second source gases. Since the second source gases which do not react with the first layer are physically adsorbed, the second source gases are moved by the purge gas. A surface of the second layer may react with the first source gas. The above-described processes form one cycle, and then the cycle is repeated several times to form a thin film.

A related art substrate processing apparatus for performing the above-described ALD method is illustrated in FIGS. 1 and 2.

FIG. 1 is a schematic perspective view of a gas injection device in accordance with a related art. FIG. 2 is a schematic sectional view of a substrate processing apparatus, to which the gas injection device of FIG. 1 is adopted, in accordance with the related art.

Referring to FIGS. 1 and 2, a substrate processing apparatus 9 in accordance with the related art includes a chamber 1 having an inner space and a substrate support part 2, on which a plurality of substrate s are seated, rotatably installed within the chamber 1. A gas injection device 3 for supplying a gas onto the substrates s is installed at the upper portion of the chamber 1.

The gas injection device 3 is constituted by a plurality of gas injection units 4. The gas injection units 4 are spaced apart from each other by a certain angle and distance along a circumference direction. Particularly, in the constitution of the gas injection device 3, a lead plate 5 having a circular plate shape is disposed on an upper portion of the gas injection device 3, and a plurality of injection plates 6 are coupled to a lower portion of the lead plate 5. The lead plate 5 has a plurality of gas injection holes 7 arrayed about a center point thereof to inject a gas to each of the gas injection units 4 through the gas injection holes 7. A gas injected through the gas injection holes 7 is diffused between the injection plates and the lead plate and is supplied to the substrates s through gas spray holes 8 arrayed in a row in the injection plates 6.

The substrate support part 2 successively receives gases from each of the gas injection units 4 while the substrate support part 2 is rotated within the chamber 1 to perform a thin film deposition process. For example, the substrate support part 2 receives a first source gas at a time point at which the thin film deposition process starts. Then, the substrate support part 2 successively receives a purge gas, a second source gas, and a purge gas to perform the thin film deposition process.

However, there is a limitation that the substrate process apparatus 9 to which the gas injection device 3 is adopted has inconstant deposition uniformity of the thin film. That is, to uniformly deposit the thin film on the entire area of a substrate s, it may be necessary to uniformly supply a gas on the entire area of the substrate s. However, when the gas injection device 3 configured as described above is used, a large amount of gas may be supplied onto a portion of the substrate s adjacent to a central side of the substrate support part 2, and also, a small amount of gas may be supplied onto a portion of the substrate s disposed at peripheral side of the substrate support part 2, with respect to the entire area of the substrate s.

To uniformly supply a gas onto the entire area of the substrate s, it is necessary to uniformly diffuse a gas introduced through the gas injection holes 7 into a space c between the injection plate 6 and the lead plate 5 and discharge the gas through the gas spray holes 8. However, as depicted with arrows in FIG. 2, the gas injected through the gas injection holes 7 is not uniformly diffused into the entire area of the space c and concentrately discharged through the gas spray holes 8 disposed at the central side of the substrate support part 2.

The substrate processing apparatus 9 illustrated in FIG. 2 adopts a so-called side pumping type in which a pumping passage P is disposed in the peripheral portion thereof. Thus, since the gas injection holes 7 are forced to be defined in the central side of the gas injection device 3, the gas is not sufficiently diffused into the inside of the gas injection device 3 due to a pressure difference between the inside of the chamber 1 and the inside of the gas injection device 3.

Furthermore, since the substrate support part 2 performs the thin film deposition process while being rotated, the peripheral portion of the substrate support part 2 is rotated by a distance greater than that by which the central side of the substrate support 2 is rotated, for the same time. Thus, even though the gas is uniformly supplied into the entire area, the amount of gas supplied to the peripheral portion of the substrate support part 2 for the same time may be decreased.

Thus, the portion of the substrate s disposed at the peripheral side of the substrate support part 2 and the portion of the substrate s disposed at the central side of the substrate support part 2 within the one substrate s may be deposited at thicknesses different from each other.

### DISCLOSURE OF THE INVENTION

### Technical Problem

The present disclosure provides a gas injection device having an improved structure to uniformly supply a gas onto the entire area of a substrate and a substrate processing apparatus using the same.

### Technical Solution

In accordance with an exemplary embodiment, a gas injection device includes: a plurality of gas injection units disposed above a substrate support part rotatably disposed within a chamber to support a plurality of substrates, the plurality of gas injection units being disposed along a circumference direction with respect to a center point of the substrate support part to inject a process gas onto the substrates, wherein each of the plurality of gas injection units includes: a top plate in which an inlet configured to introduce the process gas is provided; and an injection plate disposed under the top plate to define a gas diffusion space between the injection plate and the top plate along a radius direction of the substrate support part, the injection plate having a plurality of gas injection holes under the gas diffusion space to inject the process gas introduced through the inlet and diffused in the gas diffusion space onto the substrate, wherein, in at least one gas injection unit of the plurality of gas injection units, a partition wall is disposed between the top plate and the injection plate to divide the gas diffusion space into a plurality of separated spaces along the radius direction of the substrate support part, and the inlet is provided in plurality and the plurality of inlets are respectively provided in the separated spaces so that the process gases are independently introduced into the separated spaces.

In accordance with another exemplary embodiment, a substrate processing apparatus includes: a chamber having an inner space in which predetermined processes with respect to substrates are performed; a substrate support part on which the plurality of substrates are seated, the substrate support part being rotatably disposed within the chamber; and a gas injection device disposed above the substrate support part to inject a gas onto the substrates, the gas injection device including to the above-described constitutions.

### ADVANTAGEOUS EFFECTS

In the gas injection device and the substrate processing apparatus including the gas injection device according to the above-described embodiment, the gas diffusion space in the gas injection unit may be divided into the separated spaces along the radius direction of the substrate support part , and then, the process gas may be independently supplied to each space to uniformly supply the gas over the entire area of the substrate, thereby improving the uniformity of the thin film deposition on the substrate.

In addition, according to the embodiment, a relatively large amount of process gas may be injected through the separated space of the gas diffusion space at the peripheral side of the substrate support part than through the separated space at the central side of the substrate support part in consideration of the rotation of the substrate support part to substantially uniformly supply the gas over the entire area of the substrate.

### BRIEF DESCRIPTION OF THE DRAWINGS

FIG. 1 is an exploded perspective view of a gas injection device in accordance with a related art.

FIG. 2 is a schematic sectional view of a substrate processing apparatus to which the gas injection device of FIG. 1 is adopted.

FIG. 3 is a schematic exploded perspective view illustrating a portion of a gas injection device in accordance with an exemplary embodiment.

FIG. 4 is a schematic sectional view of a substrate processing apparatus to which the gas injection device of FIG. 3 is adopted.

FIG. 5 is a plan view of the gas injection device of FIG. 3 when viewed from a lower side.

FIG. 6 is a schematic sectional view illustrating a modified example of the gas injection unit in accordance with the exemplary embodiment.

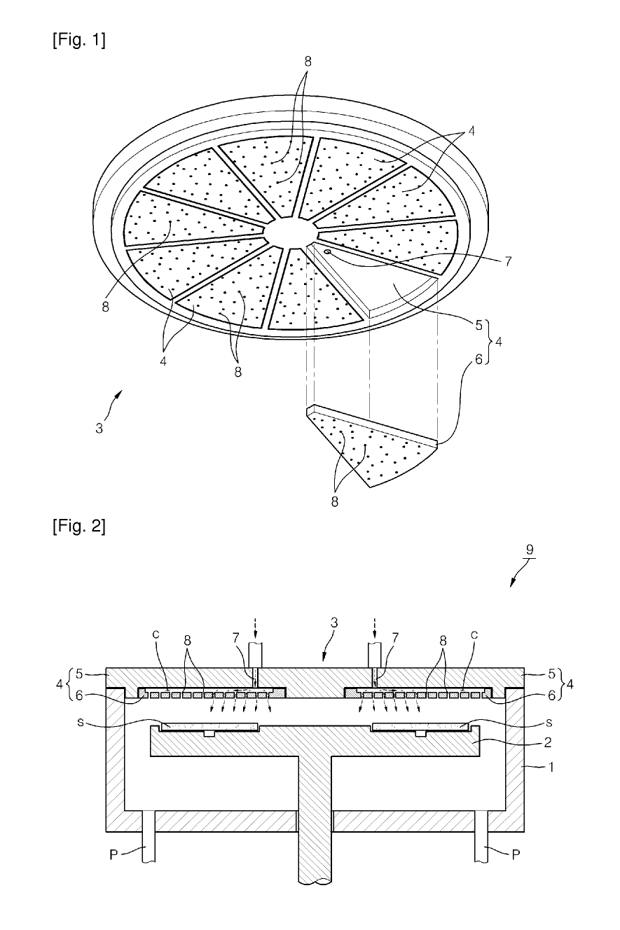

### BEST MODE CARRYING OUT THE INVENTION

According to the exemplary embodiment, each of gas introduction lines connected to an inlet disposed for each separated space may include a flow rate adjustment device to independently control a flow rate of a gas introduced into each space.

Also, according to the exemplary embodiment, gas injection units may include a plurality of source gas injection units for injecting a source gas and a plurality of purge gas injection units for injecting a purge gas. Also, two or more injection units disposed adjacent to each other to inject the same gas among the source gas injection units and the purge gas injection units may be grouped to form a gas injection block.

Also, according to the exemplary embodiments, a buffer injection unit through which a gas is selectively injected or not injected may be disposed between the plurality of gas injection units.

Also, according to the exemplary embodiments, at least two injection units among the plurality of source gas injection units and the plurality of purge gas injection units may have areas different from each other.

### MODE FOR CARRYING OUT THE INVENTION

Hereinafter, a gas injection device in accordance with exemplary embodiment and a substrate processing apparatus to which the gas injection device is adopted will be described in detail with reference to the accompanying drawings.

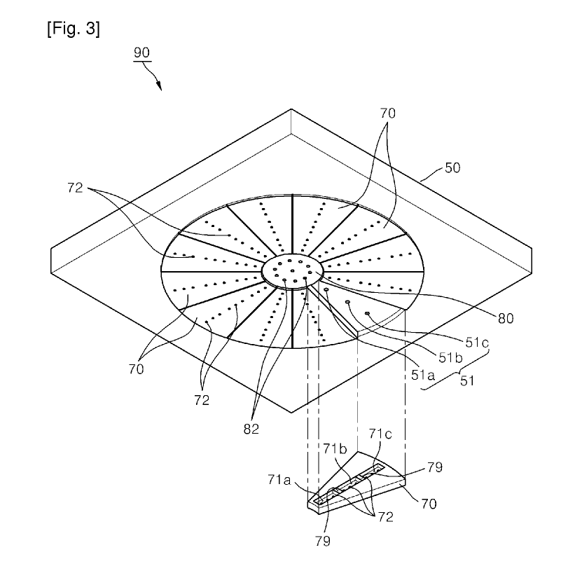

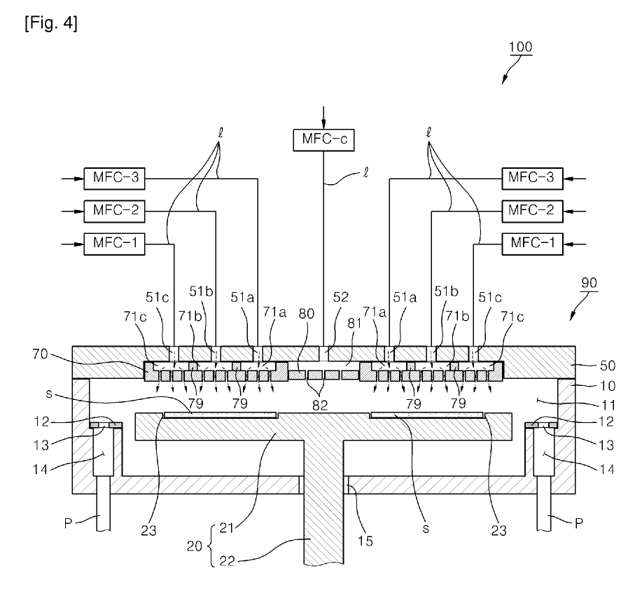

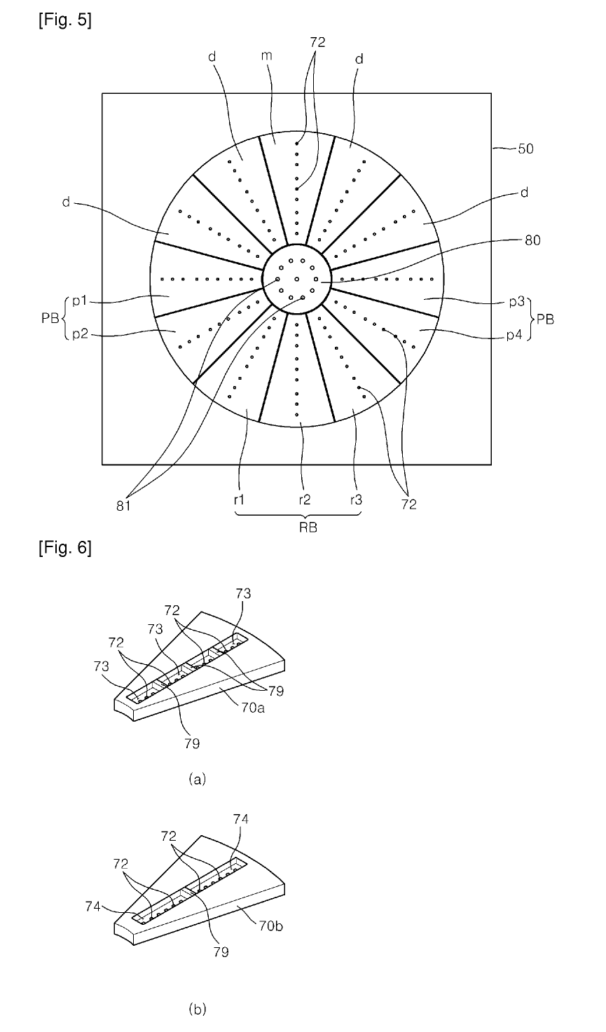

FIG. 3 is a schematic exploded perspective view illustrating a portion of a gas injection device in accordance with an exemplary embodiment. FIG. 4 is a schematic sectional view of a substrate processing apparatus to which the gas injection device of FIG. 3 is adopted. FIG. 5 is a plan view of the gas injection device of FIG. 3 when viewed from a lower side.

Referring to FIGS. 3 and 5, a substrate processing apparatus 100 to which a gas injection device in accordance with an exemplary embodiment is adopted includes a chamber 10, a substrate support part 20, and a gas injection device 90.

The chamber 10 may provide a space in which predetermined processes with respect to a substrate, e.g., a deposition process is performed. When the gas injection device 90 that will be described below is coupled to an upper portion of the chamber 10, a space part 11 is defined inside the chamber 10. Since the inner space part 11 of the chamber 10 should be generally maintained at a vacuum atmosphere, an exhaust system for exhausting a gas is provided. That is, a ring-shaped groove 14 is defined in a lower portion of the chamber 10. Also, a baffle 12 is covered on the groove 14 to define an exhaust passage surrounded by the groove 14 and the baffle 12. A pumping passage p connected to an external pump (not shown) is provided at each of both sides of the exhaust passage. A suction hole 13 is defined in the baffle 12. Thus, gases within the space part 11 are introduced into the exhaust passage through the suction hole 13, and then exhausted through the pumping passage p.

Also, a through hole 15 in which a rotation shaft 22 of the substrate support part 20 is inserted is defined in the bottom of the chamber 10. A substrate s is loaded and unloaded into/from the chamber 10 through a gate valve (not shown) disposed on a sidewall of the chamber 10.

The substrate support part 20 supports the substrate s and includes a support plate 21 and the rotation shaft 22. The support plate 21 has a flat circular plate shape. The support plate 21 is horizontally disposed within the chamber 10, and the rotation shaft 22 is vertically disposed on a lower portion of the support plate 21 within the chamber 10. The rotation shaft 22 extends to the outside through the through hole 15 of the chamber 10. Then, the rotation shaft 22 is connected to a driving unit to rotate and elevate the support plate 21. The rotation shaft 22 is surrounded by a bellows (now shown) to prevent the vacuum atmosphere within the chamber 10 from being released by a space between the rotation shaft 22 and the through hole 13.

A plurality of substrate seat part 23 are disposed along a circumference direction on an upper portion of the support plate 21. The substrate seat part 23 is recessed to prevent the substrate s from being separated to support the substrate s on the upper portion of the support plate 21 even though the support plate 21 is rotated. Also, a heater (not shown) is installed in a lower portion of the support plate 21 to heat the substrate s at a predetermined process temperature.

The gas injection device 90 injects process gases such as a source gas, a reaction gas, and a purge gas onto the plurality of substrates s seated on the substrate support part 20 and is coupled to an upper portion of the chamber 10.

In the current embodiment, the gas injection device 90 includes a plurality of gas injection units m, r1 to r3, and p1 to p4. The gas injection units m, r1 to r3, and pl to p4, each having a fan shape, are disposed along a circumference direction with respect to a center point of the substrate support part 20. Each of the gas injection units m, r1 to r3, and pl to p4 includes a top plate 50 and an injection plate 70. The top plate 50 has a square plate shape with a predetermined thickness. The injection plate 70 of each of the gas injection units m, r1 to r3, and pl to p4 is coupled to a lower portion of the top plate 50.

That is, the gas injection units m, r1 to r3, and pl to p4 may respectively occupy portions of the top plate 50 along a circumference direction of the top plate 50 to share the top plate 50. A plurality of inlets 51 having a number corresponding to the number of gas injection units m, r1 to r3, and p1 to p4 are disposed in a central portion of the top plate 50. The inlets 51 are disposed along a circumference direction with respect to a center point of the top plate 50. Each of the inlets 51 is connected to an external gas supply source (not shown).

Although the top plate may be integrally provided as described above, i.e., the injection plate of each of the gas injection units is coupled to the top plate so that the injection plates occupy portions of the top plate, the present disclosure is not limited thereto. For example, the top plate may be separately provided for each gas injection unit. That is, although not shown, in another exemplary embodiment, a frame may be coupled to an upper portion of a chamber. Then, a plurality of top plates may be coupled to the frame along a circumference direction, and an injection plate may be coupled to a lower portion of each of the top plates. The top plate as set forth in claims may be integrated with respect to all of the gas injection units or provided in plurality. In the current embodiment, the integrated top plate 50 may be described as an example.

Referring to FIG. 3, a recessed groove is defined in an upper portion of the injection plate 70. The groove is lengthily defined along a radius direction of the substrate support part 20. When the injection plate 70 is closely attached to the top plate 50, a gas diffusion space surrounded by a bottom surface of the top plate 50 and the groove of the injection plate 70 is defined along the radius direction of the substrate support part 20. Also, a plurality of gas injection holes 72 pass through the injection plate 70 in a row under the groove. The insides of the gas injection units m, r1 to r3, and pl to p4 communicate with the space part 11 of the chamber 10 through the gas injection holes 72.

In the current embodiment, partition walls 79 divide the gas diffusion space into a plurality of spaces 71a, 71b, and 71c, which are spaced apart from each other in the radius direction of the substrate support part 20. The partition walls 79 separate the spaces 71a, 71b, and 71c from each other without communicating with each other.

The top plate 50 includes inlets 51 to correspond to the gas injection units. In more detail, the inlets 51 correspond to the separated spaces 71a, 71b, and 71c of each gas injection unit, respectively. That is, referring to FIG. 5, when three separated spaces are defined in each of the gas injection unit m and the gas injection units r1, r2, and r3, three inlets 51a, 51b, and 51c for each of the gas injection unit m, r1, r2, and r3 are provided in the top plate 50.

However, although the insides of all of the gas injection units are not be divided into a plurality of separated spaces, the insides of the gas injection units for injecting the source gas as a source material for thin film deposition and the reaction gas reacting with the source gas may be divided into a plurality of separated spaces.

That is, in a thin film deposition process, the process gases introduced through the inlets 51 of the top plate 50 are be diffused in the gas diffusion space, and then, are injected onto the substrate s through the gas injection holes 72 of the injection plate 70. In this case, the process gases, particularly, the source gas and the reaction gas may be uniformly injected over the entire area of the substrate s to improve the uniformity of thin film deposition. However, as described in the related art, since a single gas diffusion space is defined between a top plate and an injection plate in a related art device, process gases introduced through an inlet are not sufficiently diffused in the gas diffusion space. In this state, the process gases are concentrately injected through the gas injection hole defined at a central side of a substrate support part. As a result, a relatively small amount of the process gases is injected through the gas injection holes disposed at a peripheral side of the substrate support part. Thus, the gases are not uniformly supplied over the entire area of the substrate s.

To address this limitation, the gas diffusion space is divided into the separated spaces 71a, 71b, and 71c, and the inlets 51a, 51b, and 51c are provided respectively to correspond to the separated spaces 71a, 71b, and 71c, thereby supplying the process gas, so that a sufficient amount of the process gases may be supplied through the gas injection holes 72 are disposed at the peripheral side of the substrate support part 20.

Flow rate adjustment devices MFC-1 to MFC-3 are installed in gas introduction lines I connected to the inlets 51a, 51b, and 51c of the separated spaces 71a, 71b, and 71c. The flow rate adjustment devices MFC-1 to MFC-3 may independently control an amount of process gas introduced to the separated spaces 71a, 71b, and 71c.

Specifically, in the current embodiment, a relatively large amount of process gas is supplied into the space 71c defined at the peripheral side of the substrate support part 20 than to the space 71a defined at the central side of the substrate support part 20. When considering the rotation of the substrate support part 20, if the same amount of gas is supplied into the spaces defined at the central side and the peripheral side of the substrate support part 20, a relatively small amount of the gas is substantially supplied onto at a peripheral side of the substrate s disposed at the peripheral side of the substrate support part 20 on the entire area of the substrate s. That is, since the substrate support part 20 is continually rotated, even though the same amount of gas is supplied over the entire area of the substrate s for the same time, a portion of the substrate s disposed at the peripheral side of the substrate support part 20 has a rotation movement distance (rotation amount) greater than that of a portion of the substrate s disposed at the central side of the substrate support part 20, for the same time. Thus, the portion at the periphery of the substrate support part 20 may have a gas contact amount less than that of the portion disposed at the central side of the substrate support part 20. Thus, a relatively large amount of process gas is supplied into the space 71c disposed at the peripheral side of the substrate support part 20 to achieve a substantially uniform gas supply over the entire area of the substrate s.

As described above, the gas diffusion space in the gas injection unit is divided into the separated spaces along the radius direction of the substrate support part 20, and then, the process gas is supplied to each space. Thus, the process gas may be uniformly supplied over the entire area of a substrate, unlike the related art, to improve the uniformity of thin film deposition.

Referring to FIG. 5, the gas injection units m, r1 to r3, and pl to p4 configured as described above are classified into a source gas injection unit m configured to inject a source gas, reaction gas injection units r1, r2, and r3 configured to inject a reaction gas, and purge gas injection units p1 to p4 configured to inject a purge gas. However, since the gas injection units have the same substantially configuration, the classification is based just on the types of gas introduced to each of the gas injection units.

That is, a gas introduced to each gas injection unit is changed according to a process to be performed, and thus the gas injection units may be variously combined and varied.

For example, in the current embodiment, the source gas injection unit expressed as a reference numeral m supplies the source gas containing a metal such as zirconium (Zr) onto the substrate support part 20, and the reaction gas injection units expressed as reference numerals r1 to r3 supply the reaction gas, such as ozone (O₃) reacting with source gas, onto the substrate support part 20. Although the source gas and the reaction gas are described separately for convenience, feed gases as set forth in the claims of the present disclosure may include the source gas and the reaction gas.

The purge gas injection units pl to p4 are disposed between the source gas injection unit m and the reaction gas injection units r1 to r3. The purge gas injection units p1 to p4 inject a non-reactive gas such as nitrogen or argon to physically remove the source gas and the reaction gas which are not chemically adsorbed to a substrate.

Also, in the current embodiment, a central purge gas injection unit 80 may be further provided in the central portion of the gas injection units to prevent the gases from being mixed between the source gas injection unit m and the reaction gas injection units r1 to r3. In the central purge gas injection unit 80, a gas introduction hole 52 is defined in the central portion of the top plate 50, and a plurality of injection hole 81 are defined under the gas introduction hole 52 to inject the purge gas onto the central side of the substrate support part 20. The purge gas is injected to form an air curtain to prevent the source gas and the reaction gas from being mutually mixed at the central side of the substrate support part 20.

In the current embodiment, the gas injection units injecting the same gas may be disposed adjacent to each other to form a gas injection block as a group.

Referring to FIG. 5, the three reaction gas injection units r1, r2, and r3 are disposed adjacent to each other to form a reaction gas block RP. Also, two groups p1 and p2, and p3 and p4 of the purge gas injection units p1 to p4 are disposed on both sides of the reaction gas injection block RB to form purge gas injection blocks PB.

Also, although not shown, the gas injection units may have different areas according to embodiments. For example, if two purge gas injection units form a purge gas injection block PB in the current embodiment, a purge gas injection unit in another embodiment may have the same area as that of the purge gas injection block PB.

In an exemplary embodiment, a buffer injection unit d is disposed between a source gas injection unit and a purge gas injection unit. The buffer injection unit d is configured to space the source gas injection unit apart from the purge gas injection unit. Also, a separate process gas is not introduced into the buffer injection unit d. However, since the buffer injection unit d has the same structure as those of other gas injection units, a process gas may be selectively introduced into the buffer injection unit d if necessary.

In the current embodiment, the two buffer injection units d are disposed between the source gas injection unit m and the purge gas injection units p1 and p2 to prevent the source gas and the purge gas from being mixed with each other.

In the current embodiment configured as described above, when the substrate support part 20 is rotated while the process gas is injected from each of the gas injection units m, r1 to r3, and p1 to p4, a plurality of substrates s seated on the substrate support part 20 are successively exposed to the source gas, the purge gas, the reaction gas, and the purge gas to deposit a thin film while forming a layer through substitution reaction between ligands of the source gas and the reaction gas on a top surface of the substrates s. In the current embodiment, the gas diffusion space in each gas injection unit is divided into the separated spaces along the radius direction of the substrate support part 20, and then, the process gas is supplied to each space. Thus, the process gas may be uniformly supplied over the entire area of the substrate s through each gas injection unit, and thus, a thin film may be uniformly deposited over the entire area of the substrate s.

Although the three separated spaces are disposed in the gas injecting unit as described above, four separated spaces may be provided as illustrated in FIG. 6A, or two separated spaces may be provided as illustrated in FIG. 6B, and thus, the number of separated spaces in the gas injecting unit is not limited.

While the present disclosure has been particularly shown and described with reference to exemplary embodiments thereof, it will be understood by those of ordinary skill in the art that various changes in form and details may be made therein without departing from the spirit and scope of the present disclosure as defined by the following claims.

What is claimed is:

1. A gas injection device comprising:
a plurality of gas injection units disposed above a substrate support part rotatably disposed within a chamber to support a plurality of substrates, the plurality of gas injection units being disposed along a circumference direction with respect to a center point of the substrate support part to inject a process gas onto the substrates,
wherein each of the plurality of gas injection units comprises:
a top plate in which an inlet configured to introduce the process gas is provided; and
an injection plate disposed under the top plate to define a gas diffusion space between the injection plate and the top plate along a radius direction of the substrate support part, the injection plate having a plurality of gas injection holes under the gas diffusion space to inject the process gas introduced through the inlet and diffused in the gas diffusion space onto the substrate,
wherein, in at least one gas injection unit of the plurality of gas injection units, a partition wall is disposed between the top plate and the injection plate to divide the gas diffusion space into a plurality of separated spaces along the radius direction of the substrate support part, and the inlet is provided in plurality and the plurality of inlets are respectively provided in the separated spaces so that the process gases are independently introduced into the separated spaces.

2. The gas injection device of claim 1, wherein a flow rate adjustment device is disposed in each of gas introduction lines connected to the inlets respectively disposed in the separated spaces to independently control a flow rat of a gas introduced into each space.

3. The gas injection device of claim 1, wherein a relatively large amount of process gas is introduced into the space defined at a peripheral side of the substrate support part than the space defined at a central side of the substrate support part among the separated spaces in the gas diffusion space.

4. The gas injection device of claim 1, wherein the gas injection unit comprises a plurality of source gas injection units configured to inject a source gas and a plurality of purge gas injection units configured to inject a purge gas.

5. The gas injection device of claim 4, wherein two or more injection units disposed adjacent to each other to inject the same gas among the source gas injection units and the purge gas injection units are grouped to form a gas injection block.

6. The gas injection device of claim 5, wherein the source gas injection units comprise injection units configured to inject the source gas and injection units configured to inject a reaction gas reacting with the source gas, and the plurality of injection units configured to inject the source gas or the plurality of injection units configured to inject the reaction gas are grouped to form a gas injection block.

7. The gas injection device of claim 4, wherein at least one injection unit of the plurality of source gas injection units and the plurality of purge gas injection units has an area different from other injection units.

8. The gas injection device of claim 1, wherein a buffer injection unit through which a gas is selectively injected or not injected is disposed between the plurality of gas injection units.

9. The gas injection device of claim 1, further comprising a central purge gas injection unit disposed at a center of the top plate to inject a purge gas.

10. The gas injection device of claim 1, wherein the top plate has one structure selected from a structure in which the top plate is integrally provided, the injection plate of each of the gas injection units is disposed along the circumference direction with respect to a center of the substrate support part to occupy a portion of the top plate, and each of the gas injection units is coupled to a lower portion of the top plate, and a structure in which the top plate is separately provided in plurality for each gas injection unit, the plurality of top plates are disposed along the circumference direction with respect to the center of the substrate support part and respectively fixed to a frame coupled to an upper portion of the chamber.

11. A substrate processing apparatus comprising:
a chamber having an inner space in which predetermined processes with respect to substrates are performed;
a substrate support part on which the plurality of substrates are seated, the substrate support part being rotatably disposed within the chamber; and
a gas injection device disposed above the substrate support part to inject a gas onto the substrates, the gas injection device according to any one of claims 1 to 10.
